(19) United States
(12) Patent Application Publication
(10) Pub. No.: US 2009/0042371 A1
(43) Pub. Date: Feb. 12, 2009

(54) LASER CRYSTALLIZATION PROCESS AND LASER PROCESS

(75) Inventor: Hung-Tse Chen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 11/972,632

(22) Filed: Jan. 11, 2008

(30) Foreign Application Priority Data
Aug. 9, 2007 (TW) 96129381

(51) Int. Cl. H01L 21/20

(52) U.S. Cl. 438/479; 257/E21.09

(57) ABSTRACT

The present invention provides a laser crystallization process applicable to a fabrication of a stack device structure. The process starts with providing a substrate having active devices formed thereon. Next, a first dielectric layer is formed on the substrate, and a multi-layer reflective layer is formed on the first dielectric layer. Then, a second dielectric layer is formed on the multi-layer reflective layer, and amorphous silicon islands are formed on the second dielectric layer. After that, a laser annealing step is performed so that the amorphous silicon islands are crystallized so as to form a poly-silicon active layer.

### CROSS-REFERENCE TO RELATED APPLICATION

This application claims the priority benefit of Taiwan application serial no. 96129381, filed on Aug. 9, 2007. The entirety of the above-mentioned patent application is hereby incorporated by reference herein and made a part of this specification.

### BACKGROUND OF THE INVENTION

1. Field of the Invention

The present invention is related to a laser crystallization process and a laser process and more particularly to a laser crystallization process applicable to a fabrication of a stack device and a laser process applicable to a flexible display panel.

2. Description of Related Art

With development of the integrated circuit, the requirement for device density becomes gradually higher, and the device size also becomes gradually smaller. In response to such trend, besides enhancing the device density by reducing the device size, satisfying the height of various types of current integrated circuits by stacking is also a good method. Currently, there are three methods for fabricating the stack device. The first method is fabricating the stack device by the wafer bonding. However, this method would cause a problem of the alignment between devices, and this problem would become even more serious as the device size gets smaller. The second method is forming an active layer of the stack device by a solid crystallization or directed deposition method. The quality of the active layer formed by such method is proportional to the temperature and time of the fabrication process. Therefore; as the device size is reduced, the temperature of the fabrication process is required to be lowered down as well, and thus the quality of the active layer would be impacted. The third method is forming the active layer by a laser crystallization method. A problem existing in this method is that the laser light causes damage to the device of the lower layer easily, and there are still problems such as bad crystallization uniformity and a rough surface of the active layer.

Furthermore, among flat display panels, the flexible display panel has been vigorously developed. Since the substrate of the flexible display panel uses organic polymer material which generally absorbs the light of the UV wave band. Therefore, when the laser of the UV wave band is used to perform a crystallization process or an activation process during the fabrication process of the flexible display panel, the substrate would become poor after absorbing the laser light. Thus, the display brightness and flexibility of the flexible display panel would be significantly influenced.

### SUMMARY OF THE INVENTION

The present invention provides a laser crystallization process applicable to a fabrication of a stack device so as to solves defect arisen when an active layer of the stack device is fabricated by the crystallization process of the prior art. Such defects includes the device of the lower layer being damaged easily, having bad crystallization uniformity and having a rough active layer surface.

The present invention further provides a laser process applicable to a fabrication of a flexible display panel. The process solves the problem that the substrate of the flexible display panel would become poor when a laser process is used to perform a conventional crystallization process or a conventional activation process.

The present invention provides a laser crystallization process applicable to a stack device structure fabrication. The process starts with providing a substrate having a plurality of active devices formed thereon. Next, a first dielectric layer is formed above the substrate and a multi-layer reflective layer is formed on the first dielectric layer. Then, a second dielectric layer is formed on the multi-layer reflective layer. A plurality of amorphous silicon islands is formed on the second dielectric layer. After that, a laser annealing step is performed so that the amorphous silicon islands are crystallized to form a poly-silicon active layer.

In the present invention, since the multi-layer reflective layer is formed underneath the amorphous silicon islands, the multi-layer reflective layer can reflect a laser light so as to prevent the active devices on the substrate from being damaged. Moreover, the present invention performs the laser annealing step on the amorphous silicon islands so that the amorphous silicon islands are laterally crystallized. Therefore, the active layer formed by such manner has better uniformity and less surface roughness.

The present invention further provides a laser process applicable to a flexible display panel fabrication. The process starts with providing a substrate. A material of the substrate includes an organic polymer material. Next, a multi-layer reflective layer is formed above the substrate. Then, a plurality of amorphous silicon islands is formed above the multi-layer reflective layer. After that, a first laser annealing step is performed so that the amorphous silicon islands are crystallized so as to form a poly-silicon active layer. The multi-layer reflective layer reflects a laser light used in the first laser annealing step.

In the present invention, since the multi-layer reflective layer is formed above the substrate, the multi-layer reflective layer can reflect the laser light so as to prevent the substrate from becoming poor for being irradiated by the laser light.

In order to make aforementioned and other objects, features and advantages of the present invention more comprehensible, preferred embodiments accompanied with figures are described in detail underneath. It is to be understood that both the foregoing general description and the following detailed description are exemplary, and are intended to provide further explanation of the invention as claimed.

### BRIEF DESCRIPTION OF THE DRAWINGS

FIGS. 1A through 1D are schematic views illustrating a laser crystallization process used for forming stack devices according to one embodiment of the present invention.

FIGS. 2A through 2D are schematic views illustrating a laser process used for fabricating a flexible display panel according to one embodiment of the present invention.

### DESCRIPTION OF EMBODIMENTS

### The First Embodiment

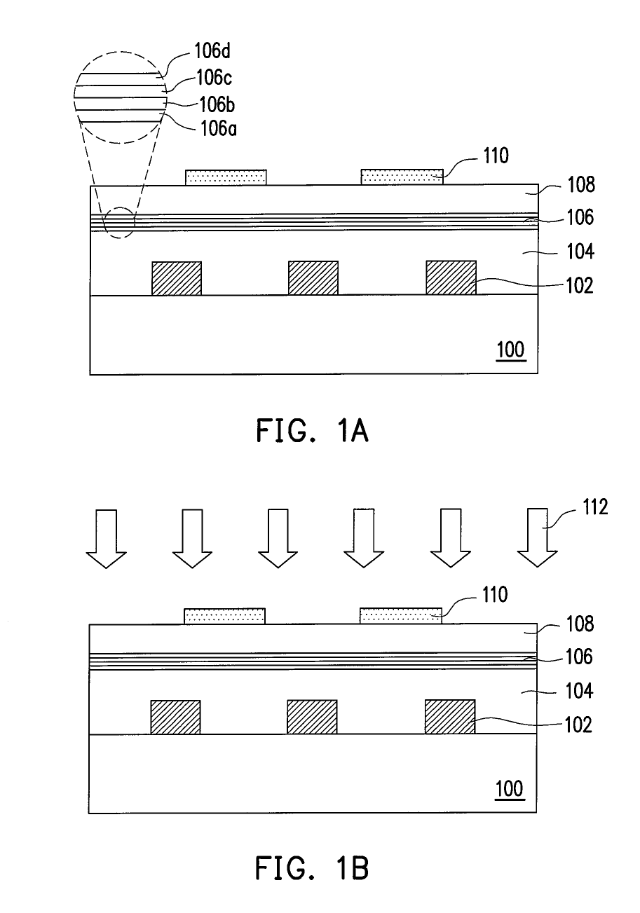

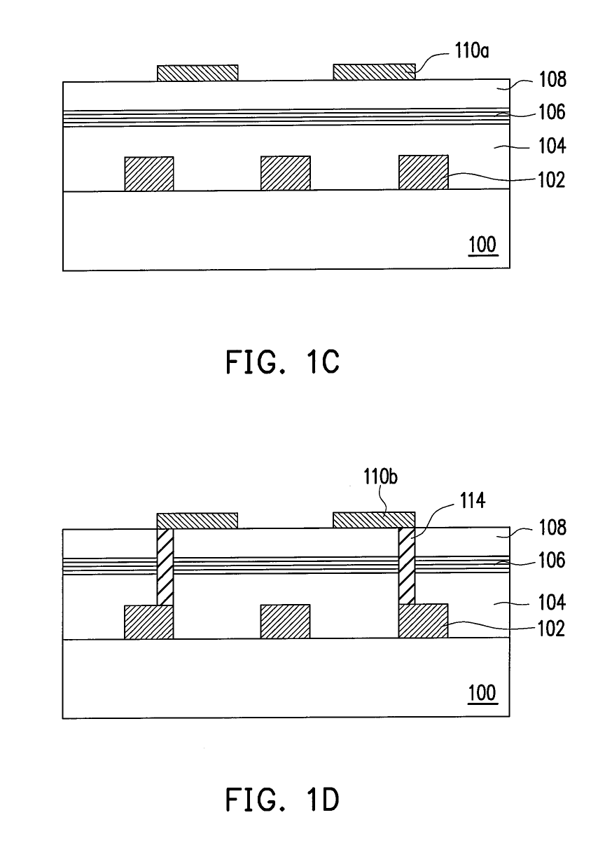

FIGS. 1A through 1D are schematic views illustrating the laser crystallization process used for forming stack devices according to one embodiment of the present invention. Referring to FIG. 1A, a substrate 100 is provided, which has a plurality of active devices 102 already formed thereon. The substrate 100 may be a wafer or a chip. The active devices 102 are metal-oxide-semiconductor (MOS) transistors, for example. A method for forming the active devices 102 on the substrate 100 adopts a semiconductor fabrication process as known in the prior art, for example. Next, a first dielectric layer 104 is formed above the substrate 100 covering the active devices 102. A material of the first dielectric layer 104 is silicon oxide, silicon nitride, for example. A method for forming the first dielectric layer 104 is a chemical vapor deposition (CVD) process or a coating process.

Then, a multi-layer reflective layer 106 is formed on the first dielectric layer 104. In one embodiment, the multi-layer reflective layer 106 is formed by alternately stacking at least one high-refractive dielectric material and at least one low-refractive dielectric material. As shown in the magnified view on the left of FIG. 1A, the multi-layer reflective layer 106 includes being formed by alternately stacking a low-refractive dielectric material 106a, a high-refractive dielectric material 106b, a low-refractive dielectric material 106c, and a high-refractive dielectric material 106d. The present invention is not intended to limit the layer number of the high-refractive dielectric materials and the low-refractive dielectric materials. Generally, two groups of the high-refractive dielectric materials and the low-refractive dielectric materials stacking alternately can well achieve a reflectivity of 70% to 80%. If the layer number of the high-refractive dielectric material and the low-refractive dielectric material is increased, the reflectivity can be further increased. Therefore, the user can decide the layer number of the high-refractive dielectric material and the low-refractive dielectric material based on actual requirements of products.

In one embodiment, thicknesses of each of the high-refractive dielectric materials and each of the low-refractive dielectric materials in the multi-layer reflective layer 106 are respectively equal to a laser light wavelength of a subsequent laser annealing step divided by four times of a index of refraction of the material or about the laser light wavelength divided by four times of the index of refraction of the material. That is, the thicknesses of each of the low-refractive dielectric material 106a, the high-refractive dielectric material 106b, the low-refractive dielectric material 106c and the high-refractive dielectric material 106d can respectively be the laser light wavelength of the subsequent laser annealing step divided by four times of the index of refraction of the material. Furthermore, the high-refractive dielectric material and the low-refractive dielectric material are respectively selected from silicon nitride, silicon oxide, tantalum oxide, titanium nitride, thorium oxide, thorium fluoride and zinc sulfide. In one embodiment, the high-refractive dielectric material is silicon nitride, for example. The low-refractive dielectric material is silicon oxide, for example. A index of refraction of the high-refractive dielectric material is between 1.72 and 3.42, for example, and a index of refraction of the low-refractive dielectric material is between 1 and 1.5. In addition, the present invention is not intended to limit to initially forming the high-refractive dielectric material or the low-refractive dielectric material, provided that at least one high-refractive dielectric material and at least one low-refractive dielectric material are stacked alternately.

Then, a second dielectric layer 108 is formed on the multi-layer reflective layer 106. Similarly, a material of the second dielectric layer 108 is silicon oxide, silicon nitride, for example. A method for forming the second dielectric layer 108 is a CVD process or a coating process.

Next, a plurality of amorphous silicon islands 110 is formed on the second dielectric layer 108. A method for forming the amorphous silicon islands 110 is, for example, initially depositing an amorphous silicon layer and then patterning the amorphous silicon layer by performing a photolithographic and an etching processes. Arrangements and positions of the amorphous silicon islands are designed based on where subsequent devices are disposed.

After that, referring to FIG. 1B, a laser annealing step 112 is performed so that the amorphous silicon islands 100 are crystallized so as to form a poly-silicon active layer 100a, as shown in FIG. 1C. In one embodiment, a temperature used in the laser annealing step 112 is lower than 450 degrees centigrade. In another embodiment, a wavelength of the laser annealing step 112 is 250 to 350 nanometers, for example. Given that the wavelength of the laser annealing step 112 is 308 nanometers, then the thicknesses of each of the high-refractive dielectric materials and each of the low-refractive dielectric materials in the multi-layer reflective layer 106 are 25 nanometers and 53 nanometers respectively (the laser light wavelength divided by the index of refraction of the material).

In the present invention, referring to FIG. 1B, the laser annealing step 112 is performed so that the amorphous silicon islands 110 are crystallized, and therefore, by controlling a grain boundary and the lateral crystallization, grains with larger sizes and better uniformity can be formed. However, since the laser annealing step 112 of the present invention is performed to scan the amorphous silicon islands 110, it results in the laser light in the laser annealing step 112 also irradiating places without the formed amorphous silicon islands 110. In other words, the laser light would pass through the dielectric layer underneath the amorphous silicon islands 110. Therefore, in the present invention, the multi-layer reflective layer 106 underneath the second dielectric layer 108 can reflect the laser light to prevent the active devices 102 underneath the multi-layer reflective layer 106 from being damaged by being irradiated by the laser light.

After forming the active poly-silicon layer 110a, referring to FIG. 1D, a series of semiconductor fabrication processes can be performed on the active poly-silicon layer 110a to form active devices 110b. Before forming the active devices 110b, it further includes forming an interconnection structure 114 in the first dielectric layer 104, the multi-layer reflective layer 106 and the second dielectric layer 108. The interconnection structure 114 can electrically connect the active devices 102 on the surface of the substrate 100 with the active devices 110b on the second dielectric layer 108 so as to form a stack device structure. Herein, a method for forming the interconnection structure 114 is an interconnection fabrication process as known in the prior art. Although the interconnection structure 114 is simply illustrated as a contact window structure in FIG. 1D, in fact, there can be multiple layers of conductive line structures, multi-layer dielectric layer and a plurality of contact window structure contained in the interconnection structure 114.

In the aforesaid embodiment, it is only exemplified that another active layer 110a (the active devices 110b) is formed above the substrate 100. In fact, in the present invention, a next active layer can be further formed above the active devices 110b to form a multi-layer stack device structure.

In the present invention, since the multi-layer reflective layer is formed underneath the amorphous silicon islands, the multi-layer reflective layer can reflect the laser light so as to prevent the active devices on the substrate from being damaged. Moreover, in the present invention, the laser annealing step is performed on the amorphous silicon islands so that the amorphous silicon islands are laterally crystallized. Therefore, the active layer formed in such manner has better uniformity and less surface roughness.

### Second Embodiment

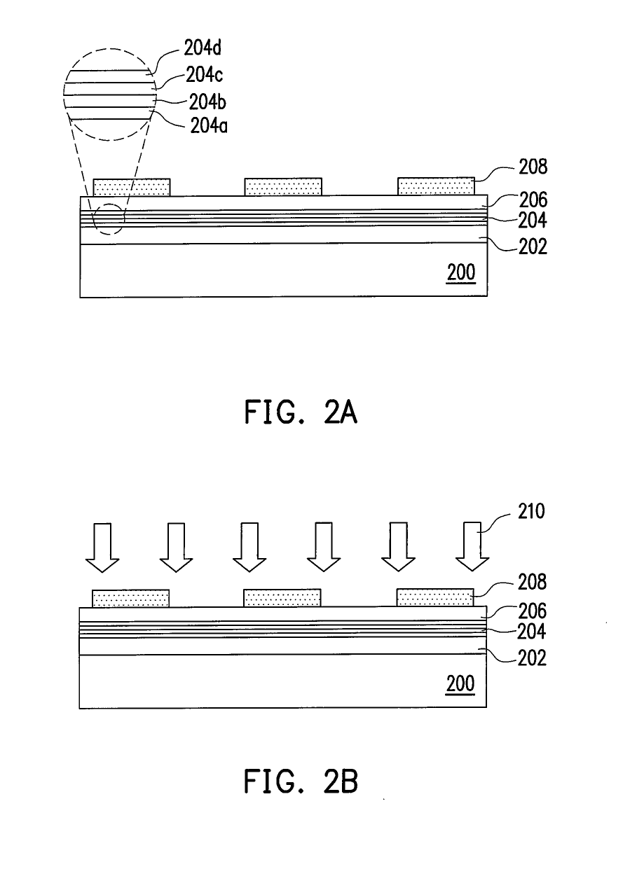

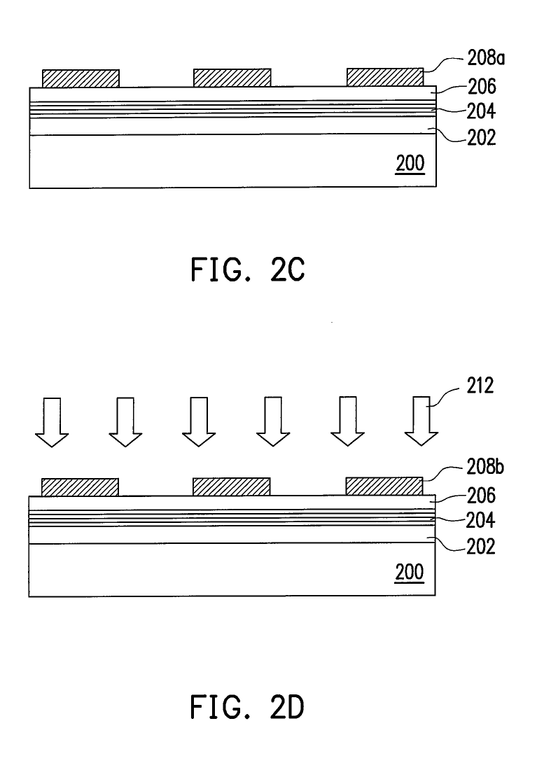

FIGS. 2A through 2D are schematic views illustrating a laser process used for fabricating a flexible display panel according to one embodiment of the present invention. Referring to FIG. 2A first, a substrate 200 is provided. A material of the substrate 200 includes an organic polymer material, such as polyimide. Generally, the substrate used for a flexible display panel is consisted of the organic polymer material, and therefore, the substrate is flexible.

Next, a multi-layer reflective layer 204 is formed above the substrate 200. In one embodiment, before forming the multi-layer reflective layer 204, it further includes forming a buffer layer 202 on the substrate 200. The multi-layer reflective layer 204 is formed by alternately stacking at least one high-refractive dielectric material and at least one low-refractive dielectric material. As shown in a magnified view on the left of FIG. 2A, the multi-layer reflective layer 204 is formed by alternately stacking a low-refractive dielectric material 204a, a high-refractive dielectric material 204b, a low-refractive dielectric material 204c, and a high-refractive dielectric material 204d. The present invention is not intended to limit the layer number of the high-refractive dielectric materials and the low-refractive dielectric materials. Generally, two groups of the high-refractive dielectric materials and the low-refractive dielectric materials stacking alternately can well achieve a reflectivity of 70% to 80%. If the layer number of the high-refractive dielectric materials and the low-refractive dielectric materials is further increased, the reflectivity can be further enhanced. Therefore, the user can decide the layer number of the high-refractive dielectric material and the low-refractive dielectric material based on actual requirements of products.

In one embodiment, thicknesses of each of the high-refractive dielectric materials and each of the low-refractive dielectric materials in the multi-layer reflective layer 204 are respectively equal to a laser light wavelength of a subsequent laser annealing step divided by four times of a index of refraction of the material or about the laser light wavelength of the subsequent laser annealing step divided by four times of the index of refraction of the material. That is, the thicknesses of each of a low-refractive dielectric material 204a, a high-refractive dielectric material 204b, a low-refractive dielectric material 204c and a high-refractive dielectric material 204d can respectively be the laser light wavelength of the subsequent laser annealing step divided by four times of the index of refraction of the material. Furthermore, the high-refractive dielectric material and the low-refractive dielectric material are respectively selected from silicon nitride, silicon oxide, tantalum oxide, titanium nitride, thorium oxide, thorium fluoride, zinc sulfide. In one embodiment, the high-refractive dielectric material is silicon nitride, for example. The low-refractive dielectric material is silicon oxide, for example. A index of refraction of the high-refractive dielectric material is between 1.72 and 3.42, for example, and a index of refraction of the low-refractive dielectric material is between 1 and 1.5. In addition, the present invention is not intended to limit to initially forming a high-refractive dielectric material or a low-refractive dielectric material, provided that at least one high-refractive dielectric material and at least one low-refractive dielectric material are stacked alternately.

Then, a plurality of amorphous silicon islands 208 is formed above the multi-layer reflective layer 204. In one embodiment, before forming the amorphous silicon islands 208, it further includes forming another buffer layer 206 on the multi-layer reflective layer 204, and a material thereof is silicon oxide, for example. A method for forming the amorphous silicon islands 208 is, for example, started with depositing an amorphous silicon layer and then patterning the amorphous silicon layer by performing a photolithographic and an etching processes. Arrangements and positions of the amorphous silicon islands 208 are designed based on where subsequent devices are disposed.

Referring to FIG. 2B, a first laser annealing step 210 is performed so that the amorphous silicon islands 208 are crystallized so as to form a poly-silicon active layer 208, as shown in FIG. 2C. The multi-layer reflective layer 204 reflects a laser light of the first laser annealing step 210. In one embodiment, a wavelength of the first laser annealing step 210 is 250 to 350 nanometers, for example.

In the present invention, referring to FIG. 2B, since the first laser annealing step 210 is performed so that the amorphous silicon islands 208 are crystallized, by controlling a grain boundary and a lateral crystallization, grains with larger sizes and better uniformity can be formed. However, since the first laser annealing step 210 is performed to scan the amorphous silicon islands 208, it results in the laser light of the first laser annealing step 210 also irradiating places without the amorphous silicon islands 208 formed. Furthermore, the substrate 200 consisted of the organic polymer material generally absorbs lights within the range of the ultraviolet light. When the substrate 200 consisted of the organic polymer material absorbs lights within the range of the ultraviolet light, it usually becomes poor so that its light transmittance becomes worse. Thus, in the present invention, the multi-layer reflective layer 204 formed above the substrate 200 can reflect the laser light to prevent the substrate 200 underneath the multi-layer reflective layer 204 from becoming poor by absorbing the laser light.

After forming the active poly-silicon layer 208a, referring to FIG. 2D, a series of semiconductor fabrication processes can be performed on the active poly-silicon layer 208a so as to form active devices 208b, such as thin film transistors. The semiconductor processes as described above include common semiconductor fabrication processes such as a deposition, an etching and an ion implantation processes. Generally, after the ion implantation process, performing an activation process is further included. In one embodiment, the activation process as described above is performing a second laser annealing step 212, as shown in FIG. 2D. A wavelength of the second laser annealing step 212 is about 250 to 350 nanometers. Similarly, when the second laser annealing step 212 is performed, a laser light used therein irradiates places without the formed active devices 208b. Thus, in the present invention, the multi-layer reflective layer 204 formed above the substrate 200 reflects the laser light of the second laser annealing step 212 to prevent the substrate 200 from becoming poor by absorbing the laser light.

In the present invention, since the multi-layer reflective layer is formed above the substrate, during the laser annealing step, the multi-layer reflective layer reflects the laser light so as to prevent the substrate from becoming poor for being irradiated by the laser light.

Although the present invention has been disclosed above by the embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A laser crystallization process, comprising:
providing a substrate having a plurality of active devices formed thereon;
forming a first dielectric layer above the substrate;
forming a multi-layer reflective layer on the first dielectric layer;
forming a second dielectric layer on the multi-layer reflective layer;
forming a plurality of amorphous silicon islands on the second dielectric layer; and
performing a laser annealing step so that the amorphous silicon islands are crystallized to form a poly-silicon active layer.

2. The laser crystallization process of claim 1, wherein the multi-layer reflective layer is formed by alternately stacking at least one high-refractive dielectric material and at least one low-refractive dielectric material.

3. The laser crystallization process of claim 2, wherein in the multi-layer reflective layer, thicknesses of each of the high-refractive dielectric materials and each of the low-refractive dielectric materials are respectively equal to a laser light wavelength of the laser annealing step divided by four times of a index of refraction of the materials or about the laser light wavelength of the laser annealing step divided by four times of the index of refraction of the material.

4. The laser crystallization process of claim 2, wherein a index of refraction of the high-refractive material is between 1.72 and 3.42, and a index of refraction of the low-refractive material is between 1 and 1.5.

5. The laser crystallization process of claim 2, wherein the high-refractive dielectric material and the low-refractive dielectric material are respectively selected from silicon nitride, silicon oxide, tantalum oxide, titanium nitride, thorium oxide, thorium fluoride, zinc sulfide.

6. The laser crystallization process of claim 1, wherein the substrate includes a chip or a wafer.

7. The laser crystallization process of claim 1, wherein the active devices on the substrate includes transistors.

8. The laser crystallization process of claim 1, further comprising forming an interconnection structure in the first dielectric layer, the multi-layer reflective layer and the second dielectric layer.

9. The laser crystallization process of claim 1, wherein a temperature used in the laser annealing step is lower than 450 degrees centigrade.

10. The laser crystallization process of claim 1, wherein a wavelength of the laser annealing step is 250 to 350 nanometers.

11. A laser process, comprising:
providing a substrate, a material thereof comprising an organic polymer material;
forming a multi-layer reflective layer above the substrate;
forming a plurality of amorphous silicon islands above the multi-layer reflective layer;
performing a first laser annealing step so that the amorphous silicon islands are crystallized so as to form a poly-silicon active layer, wherein the multi-layer reflective layer reflects a laser light of the first laser annealing step.

12. The laser process of claim 11, wherein the multi-layer reflective layer is formed by alternately stacking at least one high-refractive dielectric material and at least one low-refractive dielectric material.

13. The laser process of claim 12, wherein in the multi-layer reflective layer, thicknesses of each of the high-refractive dielectric materials and each of the low-refractive dielectric materials reflective layer are respectively equal to a laser light wavelength of a laser annealing step divided by four times of a index of refraction of the material or about the laser light wavelength of the subsequent laser annealing step divided by four times of the index of refraction of the material.

14. The laser process of claim 12, wherein a index of refraction of the high-refractive dielectric material is between 1.72 and 3.42, and a index of refraction of the low-refractive dielectric material is between 1 and 1.5.

15. The laser process of claim 12, wherein the high-refractive dielectric material and the low-refractive dielectric material are respectively selected from silicon nitride, silicon oxide, tantalum oxide, titanium nitride, thorium oxide, thorium fluoride and zinc sulfide.

16. The laser process of claim 11, further comprising forming a buffer layer on the substrate before forming the multi-layer reflective layer.

17. The laser process of claim 11, further comprising forming a buffer layer on the multi-layer reflective layer after forming the multi-layer reflective layer.

18. The laser process of claim 11, wherein a wavelength of the first laser annealing step is 250 to 350 nanometers.

19. The laser process of claim 11, further comprising:
forming a plurality of active devices on the active poly-silicon layer; and
performing a second laser annealing step so as to activate the active devices, wherein the multi-layer reflective layer reflects the laser light of the second laser annealing step.

20. The laser process of claim 19, wherein a wavelength of the second laser annealing step is 250 to 350 nanometers.
